(19) United States
(12) Patent Application Publication
(10) Pub. No.: US 2026/0322377 A1
(43) Pub. Date: Oct. 15, 2026

(54) SEQUENCE GENERATOR

(71) Applicant: Vitalthings UWB AS, Trondheim (NO)

(72) Inventors: Lieuwe LEENE, Trondheim (NO); Håkon André HJORTLAND, Trondheim (NO)

(73) Assignee: Vitalthings UWB AS, Trondheim (NO)

(21) Appl. No.: 19/109,417

(22) PCT Filed: Aug. 16, 2023
(86) PCT No.: PCT/EP2023/072520

§ 371 Date: Mar. 6, 2025

(30) Foreign Application Priority Data
Sep. 7, 2022 (GB) 2213087.6

(51) Int. Cl. H03K 17/687; H03K 19/20

(52) U.S. Cl. CPC H03K 17/6872; H03K 19/20

(57) ABSTRACT

A signal generating circuit comprising a series of cascade elements comprising a cascade input and output; a clock input, a reset element, and first and second switches connected between a high rail and a low rail. The cascade output is taken from an output node, wherein one of the high rail and the low rail is separated from the output node by both the first and second switches. The first switch is driven by the cascade input and the second switch is driven by the clock input. The cascade element has a set state and a reset state. The set state connects the cascade output to the high or low rail and the reset state connects the output to the other of the high or low rail. The second switches of any two adjacent cascade elements are arranged to be driven to opposite states by the clock input.

### BACKGROUND OF THE INVENTION

This invention relates to a signal generator circuit for the generation of baseband signals, and a baseband circuit implementing such a sequence generator.

It is known to generate signals of a desired length based on a periodic clock signal, using synchronous digital circuitry. However, the speed at which signals may be generated in such systems is limited by the fact that the interval between clock pulses must be sufficient for all of the elements of the circuit to settle to stable logic values between clock pulses for the circuit to be reliable. The maximum operating clock frequency of such circuits is therefore limited. It is possible to achieve faster operating frequencies in asynchronous analogue circuits, e.g. including delay elements, however the transition times between operations in such circuits are unreliable, and hence cannot be used to generate signals of known lengths.

The present invention provides an alternative approach.

### SUMMARY OF THE INVENTION

From a first aspect, the invention provides a signal generating circuit comprising a series of cascade elements;
wherein each cascade element comprises:
   a cascade input,
   a cascade output;
   a clock input;
   a reset element; and
   a first switch and a second switch connected in series between a high rail and a low rail;
   wherein the cascade output is taken from an output node, wherein one of the high rail and the low rail is separated from the output node by both the first and second switches;
   wherein the first switch is driven by the cascade input;
   wherein the second switch is driven by the clock input;
   wherein the cascade element has a set state and a reset state,
wherein the set state connects the cascade output to said one of the high rail and the low rail and the reset state connects the cascade output to the other of the high rail and the low rail; and
wherein the series of cascade elements comprises a plurality of cascade elements connected together in series such that any two adjacent cascade elements are connected at an intermediate node by connecting a cascade output of one cascade element to the cascade input of the adjacent cascade element,
wherein the second switches of any two adjacent cascade elements in the series are arranged to be driven to opposite states by the clock input; and
wherein at least one output signal of the signal generating circuit is provided by at least one intermediate node.

Thus it will be seen that, in accordance with this disclosure, a signal generating circuit is provided in which a plurality of alternately clocked cascade elements can be used to generate one or more output signals at predetermined and fixed times. By connecting the cascade output of each cascade element to the cascade input of an adjacent cascade element, output signals may be propagated through the series of cascade elements. As switches at adjacent cascade elements are driven to opposite states by a clock input, adjacent cascade elements are clocked alternately, such that output signals can only advance one cascade element per change of state of the clock signal. In this way, a series of cascade elements may be placed in the set state from the reset state in sequence, such that successive cascade elements in sequence only enter the set state when the cascade output of the previous cascade element has entered the set state, and the state of the clock signal changes. The output signal at each intermediate node will therefore correspond to the set state at a predetermined time, set based on the position of the cascade elements between which it is connected in the sequence. For example, in a series comprising six cascade elements, the output at the fifth intermediate node will correspond to the set state after five changes of the clock state. Output signals may thus be generated at predetermined, fixed times. The circuit of the present invention may advantageously provide output signals at precise times even when operating with a high frequency clock signal.

In some embodiments, the reset element may be connected between the output node and the other of the high rail and the low rail. The reset element may therefore be used to connect the output node to the other of the high rail and the low rail, e.g. to cause it to enter the reset state. The reset element may therefore act as a reset switch arranged to pull the cascade output to the reset state.

In some embodiments, the reset element may comprise a third switch. The third switch may be arranged to receive a dedicated reset signal to pull the cascade output to the reset state. However, in some embodiments the third switch may be arranged such that the first switch and the third switch are driven to opposite states by the cascade input such that the cascade output is disconnected from either the high rail or the low rail depending on the cascade input. For example, if the set state of a given cascade element is high (e.g. the cascade output is connected to the high rail in the set state) then the third switch may be connected between the low rail and the cascade output. Similarly, if the set state of a given cascade element is low (e.g. the cascade output is connected to the low rail in the set state) then the third switch may be connected between the high rail and the output node.

In some embodiments, the reset elements of adjacent cascade elements may be connected to opposite rails, e.g. the reset elements of adjacent cascade elements may connect the cascade outputs to the high rail and the low rail alternately. For example, if a cascade element has a reset element connected between the output node and the high rail, the reset element of the adjacent cascade element may be connected between the output node and the low rail.

In some embodiments, the second switch of each cascade element may be located between the first switch and the third switch. However, in some embodiments, both the first switch and the third switch may be located between the second switch and either the high rail or the low rail.

In some embodiments, the signal generator circuit may comprise a fourth switch in series with the first and second switches. The fourth switch may be arranged to be driven by the clock input and arranged on the opposite side of the cascade output to the second switch. By opposite side it will be understood that while one of the high rail and the low rail is separated from the output node by both the first and second switches, the other of the high rail and the low rail may be separated from the output node by the fourth switch. In such an arrangement, the second and fourth switches may be disposed symmetrically either side of the output node.

In some embodiments including a fourth switch, the second switch and the fourth switch may be arranged to be driven to opposite states by the clock input. This may ensure that for each cascade element, the cascade output is disconnected from one of the high rail and the low rail by either the second switch or the fourth switch, regardless of the state of the clock input. For example, if the clock input closes the second switch, the fourth switch will disconnect the output node from one rail, while if the clock input closes the fourth switch, the second switch will disconnect the output node from the other rail. It will be appreciated that when each of the second switch and fourth switch are closed, they potentially connect the output node to the corresponding rail, but that connection may also depend on the state of other switches in series with it.

In some embodiments, the first and second switches may be transistors. In embodiments comprising a third and/or fourth switch, the third and/or fourth switch may also be transistors, optionally FETs, e.g. MOSFETs. In some embodiments, the switches that are arranged between the cascade output and the high rail may be PMOS transistors and wherein the switches that are arranged between the cascade output and the low rail may be NMOS transistors.

In some embodiments, the cascade elements of the series may alternate between cascade elements that have a set state connected to the high rail and cascade elements that have a set state connected to the low rail. By providing cascade elements having alternating set states (e.g. such that adjacent cascade elements have their outputs connected alternately to the high rail and the low rail in the set state) and the second switches being driven to opposite states by the clock, the clock input may advantageously allow the transition of a cascade element from the reset state to the set state while preventing the transition of the adjacent cascade element to the set state. This prevents propagation of the cascade signal by more than one cascade element per clock transition and thus ensures the accurate timing of the transitions of each cascade element to its set state.

In some embodiments, the at least one output signal comprises a plurality of output signals each from an intermediate node. For example, the at least one output signal may comprise a plurality of output signals, one provided at each of the intermediate nodes.

In some embodiments, each of the plurality of output signals may be from a different intermediate node. For example, each intermediate node may be configured to provide an output signal representative of when it transitions from the reset state to the set state. In this way, a plurality of output signals may be provided, each having a transition (rising edge or falling edge) at a predetermined and fixed output time based on its position in the series of cascade elements. For example, the output signal of a fifth cascade element in the series of cascade elements will be provided at a later time than the output signal of a second cascade element in the same series.

In some embodiments, the at least one output signal may comprise a plurality of output signals that are each in the form of a rising edge or a falling edge. For example, cascade elements having a set state connected to the high rail may be used to generate rising edge signals, as the intermediate node will transition from the (low) reset state to the (high) set state at a predetermined time set based on the position of the cascade element in the series of cascade elements. Similarly, cascade elements having a set state connected to the low rail may be used to generate falling edge signals, as the intermediate node will transition from the (high) reset state to the (low) set state at a predetermined time set based on the position of the cascade element in the series of cascade elements.

In some such embodiments, the signal generating circuit may comprise a pulse generator arranged to receive two output signals and combine them into a pulse signal. The rising or falling edge of one output signal may define the start of the pulse signal and the rising or falling edge of the other output signal may define the end of the pulse signal. For example, a first output signal comprising a rising edge may be used to set the start time of the pulse signal and a second output signal comprising a falling edge may be used to set the end time of the pulse signal. By combining output signals from different cascade elements in the series, pulse signals of different start times and durations may be generated. The start time of the pulse signals may be controlled by selecting a cascade element arranged to output a rising edge at a first time, and the duration may be controlled by selecting a cascade element arranged to output at a falling edge at a second, later time, such that the duration is defined as the difference between the second time and the first time. In some embodiments, the pulse generator comprises a logical AND gate or a logical NAND gate.

In some embodiments, the pulse generator is arranged to generate a plurality of pulse signals, each pulse signal having a respective start time and duration determined by two output signals that define the start time and end time of the pulse signal respectively. This may allow the pulse generator to output multiple pulses of different start times and lengths. Each pulse output by the pulse generator may, in some embodiments, be provided to a respective weighting element to modify the amplitude of the pulse outputs and output modified pulse signals, The weighting elements may each comprise a transistor arranged to receive a pulse signal as a voltage input at its gate, and to output a modified pulse signal at its drain.

In some embodiments, the plurality of pulse signals (or modified pulse signals) may be used to generate a multi-level signal. In some embodiments, the plurality of pulse signals (or modified pulse signals) may be used to generate an envelope signal. The envelope signal may be generated by summing the pulse signals (e.g. by summing the voltages corresponding to the pulse signals directly), or may be generated by summing the modified pulse signals (e.g. taking the current sum of the modified pulse signals output by the weighting elements).

In some embodiments, the signal generating circuit may further comprise a mixer, configured to mix the envelope signal with an oscillating signal to generate a shaped pulse signal. The oscillating signal provides the carrier wave that is shaped by the envelope signal. The oscillating signal may be generated from any suitable oscillator source. However, in particularly advantageous embodiments, the oscillating signal is provided by the clock input, (or with a periodic signal generated from the clock input). As the pulse signals are generated using output signals generated based on the clock input, the clock input is common to both signals used by the mixer, i.e. it provides both the carrier wave and the envelope signal. This may advantageously ensure that the signals input to the mixer are always in phase. In some embodiments in which the envelope signal is generated from a series of square waves, it may be desirable to ensure phase alignment of the peaks of the carrier wave with the flatter, well-defined levels of the envelope signal for reliable and consistent pulse shaping.

In some embodiments, each output signal may be provided to a buffering circuit. The buffering circuit may comprise a first inverter in series with a second inverter such that the output of the second inverter provides a buffered version of the output signal and the output of the first inverter provides a buffered and inverted version of the output signal. The pulse generator may use either of these buffered signals in the generation of a pulse signal. For example, if the output signals are generated from cascade elements having a low set state (e.g. which are connected to the low rail in the set state), the output signals will all be falling edges. The output of the first inverter is therefore a buffered rising edge, and the output of the second inverter is a buffered falling edge. These signals may be provided to the pulse generator to generate a pulse signal comprising a rising edge (the output of the first inverter) and a falling edge (the output of the second inverter). Some embodiments may comprise a plurality of buffering circuits, each arranged to receive a respective output signal. The buffering circuits may therefore be used to provide rising or falling edge signals to the pulse generator circuit with timings selected based on the combination of buffered or buffered and inverted signals that produce desired timing characteristics of the generated pulse.

According to a second aspect of the invention, a signal generating circuit is provided, the signal generating circuit comprising a series of cascade elements, wherein each cascade element comprises:
a cascade input,
a cascade output;
an inverter; and
a clocking switch driven by a clock input;
wherein the inverter and the clocking switch are arranged in series between the cascade input and the cascade output;
wherein the series of cascade elements comprises a plurality of cascade elements connected together in series such that any two adjacent cascade elements are connected at an intermediate node by connecting a cascade output of one cascade element to the cascade input of the adjacent cascade element;
wherein the clocking switches of any two adjacent cascade elements in the series are arranged to be driven to opposite states by the clock input; and
wherein at least one output signal of the signal generating circuit is provided by at least one intermediate node.

In some embodiments, the signal generating circuit may comprise a reset element connected to each intermediate node. Each reset element may be arranged to selectively connect the cascade output to a high rail or a low rail, setting the cascade output to a predetermined state, e.g. a reset state. The reset element may therefore act as a reset switch arranged to pull the cascade output to the reset state. In some embodiments, the reset element may comprise a switch. The switch may be arranged to receive a dedicated reset signal to pull the cascade outputs to the reset state in response to the reset signal being received. It will be appreciated that reset elements are not essential as the reset state can simply be propagated down the chain in the same way as a cascade input. However, the use of reset elements allows all cascade elements to be returned to their reset states simultaneously for a faster reset.

According to a third aspect of the disclosure, a method of generating a shaped pulse signal is provided, the method comprising:
generating a plurality of component signals, wherein each component signal has a respective start time and duration, and wherein at least two of the plurality of component signals overlap in time;
generating an envelope signal as the sum of the component signals; and
mixing the envelope signal with a periodic signal to generate a shaped pulse signal.

According to a fourth aspect of the disclosure, a shaped pulse signal generator is provided, comprising:
a component signal generator arranged to generate a plurality of component signals, wherein each component signal has a respective start time and duration such that at least two of the plurality of component signals overlap in time;
an envelope signal generator arranged to generate an envelope signal as the sum of the component signals; and
a mixer arranged to mix the envelope signal with a periodic signal to generate a shaped pulse signal.

Thus it will be seen that, in accordance with the third and fourth aspects, a shaped pulse signal may be generated by summing a plurality of component signals to generate an envelope signal, and by mixing the envelope signal with a periodic signal. A shaped pulse signal (e.g. an amplitude modulated signal) may therefore be generated having properties set based on the properties of the time-varying component signals. In particular, the overlap of the component signals results in a higher value in the summed envelope signal. Thus, by careful alignment of the component signals, areas of overlap and areas of non-overlap can be created which determine the shape of the envelope signal and thus determine the overall shape of the shaped pulse after mixing. To achieve higher values in the summed envelope signal, three or more component signals may be overlapped at once.

In some embodiments, the envelope signal may approximate a Gaussian function having a peak amplitude, centre frequency, and pulse width. A Gaussian envelope may be particularly useful for transmissions in the unlicensed ultrawideband spectrum as it makes efficient use of the spectrum mask and is therefore power efficient.

In some embodiments, the periodic signal may be a clock signal. The clock signal may also be used in the generation of the component signals. Using a common clock signal as the periodic signal as well as to generate the envelope signal may advantageously ensure that the clock signal and the envelope signal are in phase. Such an arrangement is also more power efficient than running a separate local oscillator to generate the periodic signal as well as a clock to generate the baseband envelope signal.

The component signals may have a first state and a second state. Each of the component signals may be in the first state before its respective start time and after its respective duration (i.e. after its stop time). The first state may be a fixed amplitude state, in which the component signals each have a first fixed amplitude. The second state may be a fixed amplitude state in which the component signal has a second fixed amplitude. The first fixed amplitude may be zero.

Each of the component signals may thus have a fixed amplitude before its respective start time and after its respective duration when the component signal is in the second state. The duration of each of the component signals may correspond to the amount of time that the component signal is in the second state.

In some embodiments, the component signals may be square wave pulse signals, e.g. having a first low state and a second high state. The respective start time of each component signal may correspond to a rising edge of the square wave signal and may correspond to the component signal entering the second state. After the respective duration, the component signal may comprise a corresponding falling edge to return the component signal back to the first state.

The component signals may each have different start times. The component signals may each have different durations. The component signals may be arranged such that no two component signals have both the same start time and the same duration.

The start times of the component signals may be staggered, such that each component signal has a different start time. The time between the start time of successive component signals is preferably less than the duration of the component signals, so as to ensure that the component signals overlap in time.

The start times and durations of the plurality of component signals may be selected to generate a signal that ramps up over time. For example, the start times of the component signals may be selected such that a plurality of component signal have start times within a time period shorter than the duration of the first component signal to be generated (with the earliest start time), such that the number of overlapping component signals increases over time to a maximum value. The maximum value may be based on the sum of all of the component signals that started within the duration of the first component signal (providing none of them also ended within that time). The envelope signal formed as the sum of the component signals may thus increase in amplitude over time.

The start times and durations of the plurality of component signals may be selected to generate a signal that ramps down over time. For example, the durations of the component signals may be selected such that the number of overlapping component signals decreases over time from a maximum value. The envelope signal formed as the sum of the component signals may thus decrease in amplitude over time.

It will be appreciated that the ramping up and ramping down features may be combined to provide an envelope signal that ramps up and then ramps down. This may be achieved with a set of component signals such that when they are ordered from earliest start time to latest start time, they are also ordered from latest stop time to earliest stop time. Each component signal except the longest overlaps fully with each longer component signal.

An envelope signal that ramps up and then down may also be achieved with a set of component signals such that when they are ordered from earliest start time to latest start time, they are also ordered from earliest stop time to latest stop time. The earliest stop time may be later than the latest start time such that there will be at least one time period in which all component signals overlap. With this set, as time progresses, a gradually increasing number of component signals overlap as the start times are passed and then a gradually decreasing number of component signals overlap as the stop times are passed. This arrangement is particularly advantageous as it avoids short component signals. With the pyramid-like arrangement described in the preceding paragraph, the shortest component signal may be quite short for some pulse envelope signals. A short component signal can be hard to generate reliably at high speeds as the rising edge and falling edge are very close together resulting in a pulse that does not quite reach its peak intended level. With the alternative arrangement described in this paragraph (a more trapezoidal arrangement of component signals), all component signals can be designed with a sufficient duration that they can reach their peak intended level reliably even for high frequency, short shaped pulses. When combined with the clock sharing described above, i.e. where the same clock is used to generate both the component signals and the periodic signal so that the periodic signal and the envelope signal are generated in phase, this arrangement provides a highly reliable and consistent pulse generator.

Features of any aspect or embodiment described herein may, wherever appropriate, be applied to any other aspect or embodiment described herein. Where reference is made to different embodiments or sets of embodiments, it should be understood that these are not necessarily distinct but may overlap.

### BRIEF DESCRIPTION OF THE DRAWINGS

Certain preferred embodiments of the invention will now be described, by way of example only, with reference to the accompanying drawings, in which:

FIG. 1 is a schematic diagram of a pulse generator circuit according to an embodiment of the present disclosure;

FIG. 2 is a schematic diagram of a signal generator of the pulse generator circuit according to an embodiment of the present disclosure;

FIGS. 3a and 3b show schematic diagrams of an inverter and buffer circuit of the pulse generator circuit according to an embodiment of the present disclosure;

FIG. 4 is a timing diagram of signals generated in the pulse generator circuit according to an embodiment of the present disclosure;

FIG. 5 is a schematic diagram of a baseband sequence generator according to the present disclosure in a radio frequency transmitter circuit;

FIG. 6 is a timing diagram of the generation of a baseband signal for RF transmission using a baseband circuit according to an embodiment of the present disclosure;

FIG. 7 is a schematic diagram of a signal generator according to an embodiment of the present disclosure;

FIG. 8 is a schematic diagram of a signal generator according to an embodiment of the present disclosure;

FIGS. 9a and 9b illustrate timing diagrams of signals generated by signal generators according to embodiments of the present disclosure;

FIG. 10 is a schematic diagram of a signal generator according to an embodiment of the present disclosure; and

FIG. 11 is a schematic diagram of a signal generator according to an embodiment of the present disclosure.

### DETAILED DESCRIPTION

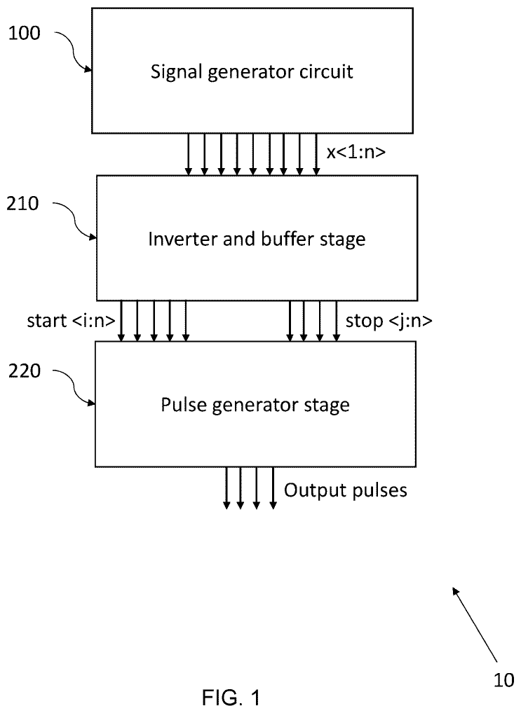

FIG. 1 shows a pulse generator circuit 10 according to the present disclosure. The pulse generator circuit 10 is arranged to generate a plurality of output signals, each having a predetermined duration and start time. For example a first output signal may have a start time defined by a particular rising or falling clock edge, e.g. the 5^{th} rising clock edge in a sequence of clock pulses, and may have a duration defined by a first predetermined number of pulses of the clock, while a second output signal may have a start time defined by the 12^{th} rising clock edge and have a duration defined by a second predetermined number of pulses of the clock. Specifically, the pulse generator circuit 10 is arranged to generate a plurality of output signals that are initially logic low, transition to logic high at predetermined respective times and remain logic high for predetermined respective durations, before transitioning back to being logic low, e.g. square wave pulses. Each of the output signals may have different timings, e.g. some output signals may have longer durations than others, and may initially transition from logic low to logic high at different times.

The pulse generator circuit 10 comprises three stages, which will be described in more detail in the following. The first stage of the pulse generator circuit 10 is a signal generator circuit 100, which is arranged to output multiple rising and/or falling edge signals x<1:n> in sequence. The rising and/or falling edge signals x<1:n> are output to a inverter and buffer circuit 210 that generates inverted rising/falling edge signals start<i:n> and buffered rising/falling edge signals stop <j:n> that are passed to a pulse generator circuit 220 and used to select and control the start and stop timings of pulses output by the pulse generator circuit 10.

As will be explained in the following, the properties of the output pulses, e.g. their respective durations, can be controlled by appropriate selection of the components of the signal generator circuit 100.

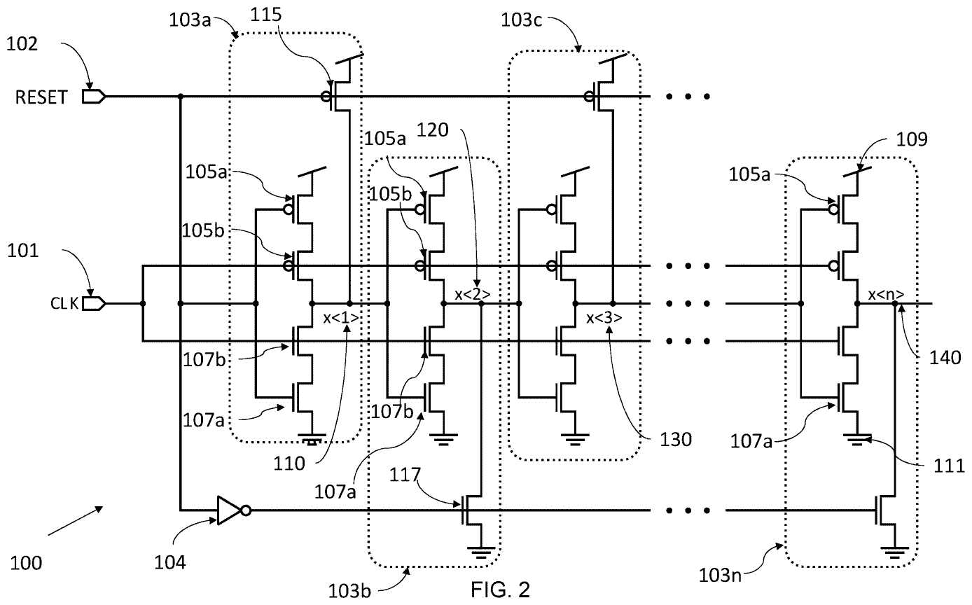

The signal generator circuit 100 is shown in detail in FIG. 2. The signal generator circuit 100 comprises two inputs 101, 102 arranged to receive signals with timings that control the operation of the signal generator circuit 100. In particular, the timing of a clock signal received at a first input 101 (referred to hereinafter as the clock input) of the signal generator circuit 100 from a clock source, as well as the timing of a ‘resetting’ signal received at a second input 102 (referred to hereinafter as the reset input) of the signal generator circuit 100, may be used to control the generation of multiple rising and/or falling edge signals x<1:n> as will be explained in the following.

The signals received at the clock input 101 and the reset input 102 are provided to a cascade of core elements 103 (which may also be referred to as cascade elements), which are connected in sequence. By ‘in sequence’ it will be understood that while a first core element 103a is connected to the clock input 101 and the reset input 102 directly, a second core element 103b is connected to the reset input 102 via the first core element, and that further core elements are connected to the reset input 102 via core elements 103 that are earlier in the sequence. For example, in the embodiment shown in FIG. 2, the third core element 103c is connected to the reset input 102 via the second core element 103b and the first core element 103a. The clock input 101 is connected to each of the core elements 103 directly, i.e. such that clock signals are received at each of the core elements effectively simultaneously. However, the reset signal received at the first core element 103a from the reset input 102 is used to generate a cascade signal that is received at the second core element 103b, and propagated to the other core elements 103 as will be described in the following.

Although four core elements 103a, 103b, 103c and 103n are shown in FIG. 2, it will be appreciated that the signal generator circuit 100 may include fewer, e.g., two or three, core elements, or could include a greater number of core elements, e.g., five, ten, one hundred core elements etc., as represented by the dotted line between the third core element 103c and the nth core element 103n in FIG. 2. The number of core elements present in the signal generator circuit 100 may be selected based on the required properties of the pulse generator circuit 10 in which the signal generator circuit 100 is situated. If a greater variety of output pulses (e.g. many pulses of different durations or of longer durations) are required, more core elements 103 may be included in the signal generator circuit 100.

Each of the core elements 103 is arranged to generate a respective rising/falling edge signal x<i> based on the clock signal and the cascade signal from the previous core element, as the cascade signal propagates through the cascade of core elements 103.

In FIG. 2, the cascade signal to the first core element 103a is provided by the reset signal. However, it will be appreciated that this arrangement is for convenience in this particular implementation and is not essential. In other embodiments the first core element 103a may receive a starting cascade signal from an alternative source, not necessarily linked to the reset signal.

The core elements 103 each comprise a plurality of ‘core’ PMOS transistors 105a, 105b and NMOS transistors 107a, 107b and a further ‘reset’ transistor, which may be either a PMOS reset transistor 115 or an NMOS reset transistor 117, depending on the desired reset state of the core element 103 with which it is associated in the sequence of core elements 103. In the embodiment shown in FIG. 1, each of the core elements 103 includes two core PMOS transistors 105a, 105b and two core NMOS transistors 107a, 107b connected in series between a voltage supply rail 109 and ground 111, as well as a PMOS reset transistor 115 or an NMOS reset transistor 117 connected to the reset input 102 and arranged to receive the reset signal. Although the PMOS reset transistors 115 are connected to the reset input 102 directly, the NMOS reset transistors 117 are connected to the reset input 102 via an inverter 104, such that the reset signal 102 has the same effect on both the PMOS reset transistors 115 and the NMOS reset transistors 117 (i.e. all reset transistors 115, 117 are switched to a conducting state or all reset transistors 115, 117 are switched to a non-conducting state by the reset signal 102). Core elements 103 that have a reset transistor connecting the output node x<i> to the voltage supply rail effectively have a high reset state (and conversely a low set state). Core elements 103 that have a reset transistor connecting the output node x<i> to the ground rail effectively have a low reset state (and conversely a high set state).

Two types of core element 103 are present in the signal generator circuit 100, having either a PMOS reset transistor 115 (e.g. 103a, 103c in FIG. 1) or an NMOS reset transistor 117 (e.g. 103b, 103n in FIG. 2). As shown in FIG. 2, the two types of core element 103 are cascaded alternately, such that a core element 103 having a PMOS reset transistor 115 is followed in the sequence of core elements 103 by a core element having an NMOS reset transistor 117, which is followed in the sequence of core elements 103 by a core element having an PMOS reset transistor 115, and so on. The reset states of these core elements alternate between high and low and the set states of these core elements therefore also alternate between high and low. It will be appreciated that this alternation of set states is not essential and that with suitable control logic it is possible for two adjacent core elements 103 to both have high set states or high reset states.

One PMOS transistor 105a and one NMOS transistor 107a of each core element 103 are connected to form an inverter arranged to receive a cascade signal output by the preceding core element (and in the case of the first core element 103a, to receive the reset signal from the reset input 102 or an initial cascade input from an alternative source), and to generate a cascade signal x<i> at an output node in response. The cascade signal x<i> output of each of the core elements 103a-103n is shown in FIG. 1 as x<1>, x<2>, x<3> and x<n> at the output nodes 110, 120, 130 and 140 respectively.

The two other core transistors 105b, 107b of each core element 103 shown in FIG. 2 are arranged to receive the clock signal from the clock input 101, such that each of the core elements 103 forms a clocked inverter. As can be seen in FIG. 2, the two core transistors 105b, 107b that receive the clock signal 101 comprise a PMOS transistor 105b and an NMOS transistor 107b such that only one of these transistors is switched on by the clock signal 101, i.e. these two transistors 105b, 107b are driven to opposite states by the clock signal 101.

As successive core elements 103 are arranged to receive a cascade signal output by the preceding core element 103, they are each arranged to output a signal with a value and timing that depends on the cascade signal output by the previous core element 103, as will be explained in the following.

The reset transistors 115, 117 are used to prevent drift at the nodes 110, 120, 130 140 of the signal generator circuit 100 when it is not in use, by holding the core elements 103 in a reset state. Specifically, when the circuit is not in use, the signal received at the reset input 102 is set to remain low, and the signal received at the clock input 101 is also set to remain low (e.g. the clock received by the signal generator circuit 100 remains off). In the reset state, the voltage at the output node of each core element 103 (and hence each of the output signals x<1>-x<n>) is held in a reset state. For core elements 103 having a PMOS reset transistor 115, the reset state is high, and the output node is pulled up by the PMOS reset transistor 115. For core elements having an NMOS reset transistor 117, the reset state is low, and the output node is pulled down by the NMOS reset transistor 117. Thus, in the reset state, the outputs of each of the core elements 103 are held at a fixed potential. This ensures that the output at each node does not drift over time as a result of leakage currents.

To start the signal generator circuit 100, e.g. to switch the circuit into an active or operational state, the signal received by the signal generator circuit 100 at the reset input 102 is switched from low to high, and the clock received by the signal generator circuit 100 at the clock input 101 is started. When the reset signal switches high, the PMOS reset transistors 115 and NMOS reset transistors 117 are switched to a non-conducting state such that the respective output nodes x<i> are decoupled from the power and ground rails respectively. As a result, the nodes between each core element 103 become floating and remain floating until they are connected to a power rail or ground rail through the preceding core element 103.

The cascade signal thus begins to propagate through the cascade of core elements 103, advancing one core element for each rising and for each falling edge of the clock signal. At each core element 103, the clock signal causes the state of the core element 103, and hence its output, to change, e.g. from low to high or from high to low. As the output of each core element 103 changes, its respective node ceases to be floating, and is instead driven to its set state by the set state of the preceding core element 103. In the example shown in FIG. 2, one of the clocked transistors will periodically disconnect the output node from the rail that defines its set state, but will also periodically connect the output node to that rail so that the set state is continually refreshed rather than left floating. By contrast, the core element 103 remains continually disconnected from the reset state during this time.

For example, for the first core element 103a, in the reset state, the signals received at the clock input 101 and the reset input 102 (which provides the initial cascade input) are both low initially, the output x<1> is pulled up by the core PMOS transistors 105a, 105b and the PMOS reset transistor 115, such that the node 110 and the output x<1> are high. When the signal received at the reset input 102 transitions high, the output node 110 is disconnected from the voltage supply rail at the source of the PMOS reset transistor 115 as the PMOS reset transistor 115 is switched off. Similarly, the output node 110 is also disconnected from the voltage supply rail at the source of the uppermost PMOS transistor 105a that is driven by the initial cascade input. This causes the output x<1> of the first core element 103a to become floating while the clock input 101 is also low. If it were to be left in this state, the output x<1> would remain high for a time before leakage currents caused it to drop. It is for this reason that the signal generator circuit 100 is held in the reset state when not in use. However, when in use, the signal received at the clock input 101 transitions high shortly after the signal received at the reset input 102 becomes high, e.g. after several picoseconds. The high clock signal causes the core PMOS transistor 105b to be disconnected from the voltage supply rail 109, and causes the NMOS transistor 107b to connect the output node 110 to ground 111, such that the output node 110 is pulled low (corresponding to the set state of the first core element 103a). The output node 110 therefore switches from high to low when the clock signal 101 is received by the first core element 103a, causing a falling edge in the output signal x<1>. This acts as the first step in the clocked propagation of the cascade signal through the cascade of core elements 103.

Looking to the second core element 103b, its input (i.e. the output x<1> of the first core element 103a), will initially be high while the signal generator circuit 100 is in the reset state and its output 120, x<2> will be low, pulled to ground by the NMOS reset transistor 117. When the reset input 102 transitions high, the output of the second core element 103b becomes floating as explained above. When the clock signal 101 transitions high, and the output x<1> consequently transitions to low as discussed above, the core PMOS transistor 105a of core element 103b becomes conducting, but the PMOS clock transistor 105b of the core element 103b remains non-conducting until the clock signal 101 transitions to low, such that the output node 120 remains disconnected from its set state (high) until the clock signal 101 transitions low. When the clock input 101 does go low, both of the two core PMOS transistors 105a, 105b of the second core element 103b will be conducting and will pull the output x<2> of the second core element 103b high (i.e. to its set state). The second output node 120 therefore switches from low to high when the clock signal 101 switches from high to low, causing a rising edge in the output signal x<2>. This acts as the second step in the clocked propagation of signals through the cascade of core elements 103.

The output signal x<2> forms the input to the third core element 103c, and hence this signal continues to propagate through the cascade of core elements 103 as the clock signal received at the clock input 101 transitions back and forth from high to low. As the core elements have alternating set states (alternating between high and low) and the transition to the set state requires the clocked transistor (105b or 107b) to be in a conducting state, the clock signal will always disable the transition of the next core element in sequence while it is allowing the transition on one core element. In this way, the output of each of the ‘odd numbered’ core elements 103 (e.g. core elements 103a, 103c in FIG. 1) start high and transition low at a predetermined time, while the output of even numbered core elements 103 (e.g. core elements 103b, 103n) start low and transition high at a predetermined time. The state of each core element 103 depends on the state of the previous core element 103 in the sequence, and hence it won't change until the state of the previous core element 103 has flipped and the next rising/falling edge of the clock signal is received. The time at which the state of each core element 103 changes therefore relies on the frequency of the clock signal received at the clock input 101, as well as the position of each core element in sequence. For example, the time at which the fourth core element in sequence changes will depend on the time taken for 2 clock pulses (and hence four clock edges) to be generated and the length of each clock pulse (which is set by the frequency of the clock signal).

It will be appreciated that in other examples where the set state and reset state of adjacent core elements are not alternating, additional inversion of the clock signal may be required to ensure that adjacent core elements 103 are not simultaneously enabled. Instead, the additional inversion can ensure that the clock signal will disable at least one of any two adjacent core elements 103, thereby preventing propagation of the cascade signal until the next clock edge.

When the cascade signal has passed through all of the core elements 103 of the signal generator circuit 100, the circuit is returned to the reset state by stopping the clock input signal (such that it remains low) and setting the reset input 102 to low. This causes the reset transistors 115 and 117 to become conductive, and pull their respective output nodes to the reset state, i.e. high for the odd numbered core elements 103 having a PMOS reset transistor 115, and low for the even numbered core elements 103 having an NMOS reset transistor 117. This ensures that the nodes 110, 120, 130, 140 etc. do not become floating and hence are not affected by leakage currents that could otherwise alter the high/low states.

By propagating the output signals of each core element 103 through the signal generator circuit 100, an output signal is generated for each odd numbered core element 103 that starts out low, then switches high after a predetermined time specific to that core element 103 (dependent on the location of the core element 103 in the sequence and the clock cycle), and switches low at a later predetermined time, e.g. when the reset signal is switched low. An output signal is also generated for each even numbered core element 103 that starts out high, then switches to low at a predetermined time specific to that core element, and switches to high at a later predetermined time. In this way, output signals x<1:n> can be generated in sequence, including falling edges and rising edges alternatively.

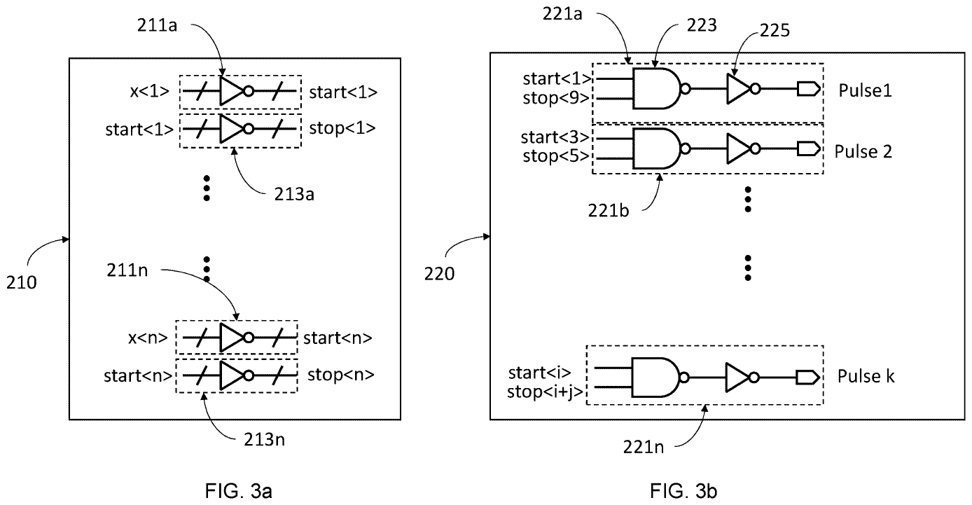

The output x<i> of each of the core elements 103 is provided to the inverter and buffer stage 210 of the pulse generator circuit 10, shown in more detail in FIG. 3a. The inverter and buffer stage 210 of the signal generator circuit 100 comprises two sets of inverters 211, 213. Each of the first set of inverters 211 is arranged to receive the output x<i> of one of the core elements 103 of the signal generator circuit 100, and to generate a respective inverted signal start<i> as an output. Each of the second set of inverters 213 is arranged to receive the output start<i> of one of the inverters 211, and to generate a respective ‘buffered’ signal, stop<i>, as an output, i.e. matching the x<i> signal used to generate the inverted start<i> signal.

The buffered signal stop<i> and the inverted signal start<i> are used to set the start and stop times of pulses generated by the pulse generator circuit 10, at the pulse generator stage 220 of the pulse generator circuit 10, shown in more detail in FIG. 3b. The third part 220 of the circuit 100 contains a plurality of sequence elements 221 that each performs logical conjunction using a NAND gate 223 and an inverter 225. The NAND gate 223 takes a start<i> signal and a stop<i+j> signal as inputs, where i and i+j are both odd numbered, and outputs a pulse that starts according to the start<i> signal, and stops according to the stop<i+j> signal. The signal output by the NAND gate is a negative amplitude pulse which is provided to the inverter 225 to ensure a positive pulse is present in the output signal. These resulting pulses generated by each sequence element 221 may then be output by the pulse generator circuit 10 as an output signal. The inverter and buffer stage 210 and the pulse generator stage 220 of the pulse generator circuit 10 therefore allow output signals to be generated with timings selected based on the combination of start<i> and stop<i+j> signals that produce desired timing characteristics.

Although an AND gate may be used in place of the NAND gate 223 and inverter 225, a NAND gate is preferred in at least some embodiments, due to the speed at which it processes inputs being greater than that of an AND gate or other CMOS logic components.

It will also be appreciated that similar results can be achieved by combining input signals from both even and odd numbered core elements with appropriate negation at the input to the AND or NAND gate. Similar results can also be achieved with an OR gate or NOR gate and suitable negation of the input and output.

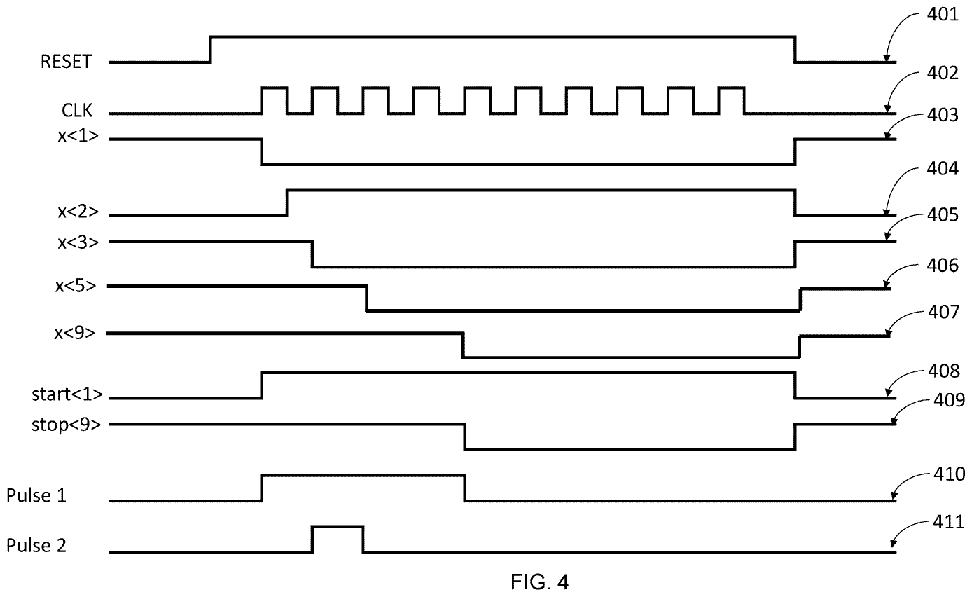

An example of timings of signals in the signal generator circuit 100 is shown in FIG. 4. FIG. 4 shows a timing diagram for a range of signals used in the pulse generator circuit 10 shown in FIGS. 1-3.

Curve 401 shows how the signal received at the reset input 102 changes during operation of the signal generator circuit 100. As described above, the reset signal is initially low when the signal generator circuit 100 is off, and transitions to high when the signal generator circuit 100 is in use. When the signal generator circuit 100 again enters the reset state, the reset signal returns to being low.

Curve 402 shows the clock signal received at the clock input 101 during operation of the signal generator circuit 100. The clock signal is initially low while the signal generator circuit 100 is in the reset state. When the signal generator circuit 100 is running, the clock repeatedly transitions between low and high states at times set based on the frequency of the clock signal. When the signal generator circuit 100 again enters the reset state, the clock is turned off and the clock signal remains in the low state.

Curves 403, 404 and 405 show the output signals at the output nodes 110, 120 and 130 of the core elements 103a, 103b and 103c respectively. As described above, the odd numbered core elements 103a and 103c are initially high in the reset state, but transition low after a respective predetermined period. The even numbered core elements, e.g. 103b, are initially low in the reset state, but transition high after a respective predetermined period. The sequential nature of the transition from the reset state for each of the core elements 103 can be clearly seen in FIG. 4. In particular, it can be seen that the first core element 103a is the first to transition from its initial (high) state when the first clock rising edge appears. The second core element 103b can be seen to change state only once the output x<1> from the first core element 103a changes (i.e. from high to low) and the clock first falling edge appears, and the third core element 103c can be seen to change state only once the output x<2> from the second core element 103a switches from low to high and the second clock rising edge appears.

Two further exemplary output signals, from the fifth and ninth core elements 103 in sequence, are shown in FIG. 4 as curves 406 and 407 respectively. As both the fifth and ninth core elements are odd-numbered, and have PMOS reset transistors, their output signals, x<5> and x<9> respectively, are initially high in the reset state, but transition low after a respective predetermined period, in a manner equivalent to the first core element 103a. These examples more clearly demonstrate the sequential nature of the transition from the reset state for each of the core elements 103, i.e. that the time at which the state of the output of each core element 103 switches depends on its order in the sequence of core elements 103.

FIG. 4 also shows that the output signals x<1>, x<2> and x<3> all revert to their respective initial states (reset states) when the signal generator circuit 100 again enters the reset state (e.g. when the clock signal received at the clock input 101 and the reset signal received at the reset input 102 switch back to low). It can therefore be seen that the first part of the signal generator circuit 100 outputs a plurality of output signals, e.g. x<1>, x<2> . . . x<n> of different respective start times and durations.

As described above, the output x<i> of each of the core elements 103 is provided to the inverter and buffer stage 210, which is used to generate a plurality of start<i> and stop<i+j> signals, used to set the start and end times of pulses generated by the pulse generator circuit 10.

The start<1> signal output by the inverter and buffer stage 210 of the pulse generator circuit 10 using the output of the first core element 103a is shown in FIG. 4 as curve 408. As described above, the start<1> signal is the result of passing the x<1> signal through an inverter, and can be seen to be a simple inversion of the signal x<1> output at the node 110.

Curve 409 shows a buffered signal, stop<9>, generated from the output x<9> of the ninth core element shown in curve 407. As outlined above in relation to FIG. 3a, the buffered signal is generated by passing the output x<9> of the ninth core element 103 through a first inverter to generate a respective inverted signal start<9> (not shown in FIG. 4), and by passing the start<9> signal through a further inverter to generate the buffered signal stop<9> which matches the x<9> signal but has a small delay relative to the output signal x<9> of the ninth core element. In line with the other odd-numbered core elements, the stop<9> signal generated based on the output x<9> of the ninth core element can be seen to start high and transition low at a predetermined time, later than the earlier core elements in sequence.

Curves 410 and 411 show the outputs of two sequence elements 221 of the pulse generator stage 220 of the signal generator circuit 10. Curve 408 shows the output of a sequence element 221a (shown in FIG. 3b) that takes, as input, the start<1> signal generated from the output of the first core element, and the stop<9> signal generated from the output x<9> of the ninth core element. Curve 410 shows that the sequence element 221a generates a pulse that starts according to the start<1> signal (i.e. having a rising edge that coincides with that of the start<1> signal), and stops according to the stop<9> signal, (i.e. having a falling edge that coincides with that of the stop<9> signal).

Curve 411 shows the output of a sequence element 221b (shown in FIG. 3b) that takes, as input, the start<3> signal generated from the output x<3> of the third core element 103c, and the stop<5> signal generated from the output x<5> of the fifth core element 103. The curve 411 shows that the sequence element 221b generates a pulse that starts according to the start<3> signal (i.e. having a rising edge that coincides with that of the start<3> signal), and that stops according to the stop<5> signal (i.e. having a falling edge that coincides with that of the stop<5> signal). The duration of the pulses generated by the sequence elements 221 of the pulse generator stage 220 of the signal generator circuit 10 can therefore be seen to be set based on the rising edge of the start signal, and the falling edge of the stop signal, that are input to the NAND gate of the sequence element 221.

By taking the outputs x<1> to x<n> of the core elements 103 of the signal generator circuit 100, inverting and buffering their outputs in the inverter and buffer stage 210, and providing the outputs of this stage to the sequence elements 221 of the pulse generator stage 220, pulses can be generated having start times and durations that can be controlled through appropriate selection of pairs of core elements 103 and the frequency of the input clock. For example, narrow pulses can be generated by selecting pairs of core elements 103 that are close to one another in the sequence of core elements 103 (as shown in curve 411 in FIG. 4), while pulses of longer duration can be generated by selecting pairs of core elements 103 that are located further apart in the sequence (as shown in curve 410 in FIG. 4). The start time of the pulses can also be controlled, e.g. core elements earlier in the sequence can be used to generate pulses having earlier start times.

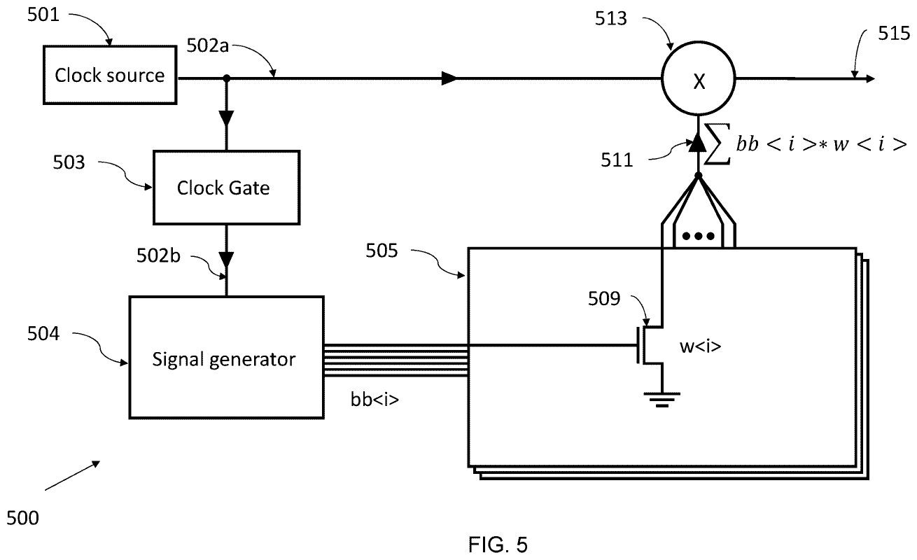

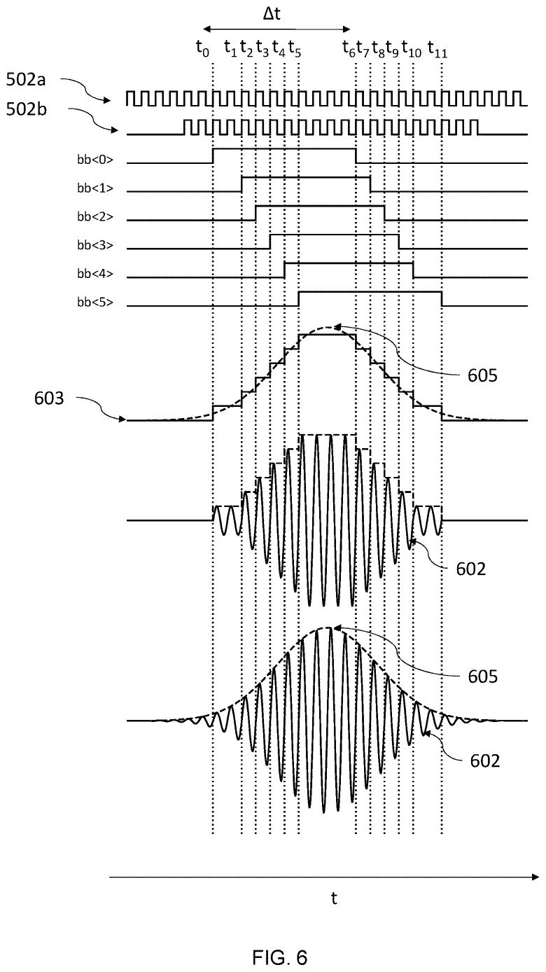

Having outlined how the signal generator circuit 10 can be used to generate pulses of controllable start time and duration, the use of such pulses in the generation of mixer signals, e.g., for radio frequency transmission is described below with reference to FIGS. 5 and 6.

FIG. 5 shows a pulse generator 500 for use in, e.g. an RF transmitter. The pulse generator 500 includes a clock source 501 that provides a clock signal 502a, which is converted to a gated clock signal 502b after passing through a clock gate 503 and provided to a signal generator circuit 504. The signal generator circuit 504 may be the signal generator circuit 10 shown in FIGS. 1 to 3, but may also be any other signal generator that allows similar pulses to be generated and output. The gated clock signal 502b provides the clock signal 502a to the signal generator circuit 504 when required and blocks the clock signal 502a (e.g. outputs a continuous low signal) at other times, i.e. the gated clock signal may take the form shown in curve 402 of FIG. 4.

The signal generator circuit 504 outputs a plurality of baseband component signals bb<i> to respective transistors 509. FIG. 5 shows multiple layers 505 each having a single transistor 509. For simplicity, FIG. 5 only shows three layers, but it will be appreciated that the number of layers (i.e. the number of transistors 509) is equal to the number of baseband component signals bb<n> output by the signal generator circuit 504. The baseband component signals bb<i> each comprise a pulse of predetermined start time and duration, and are generated such that the signal generator circuit 504 outputs multiple baseband component signals bb<i>, each comprising a pulse of predetermined length and start time. The baseband signals bb<i> may, in some embodiments, correspond to the pulses output by the pulse generator stage 220 of the signal generator circuit 10 shown in FIGS. 1 to 3. The baseband component signals bb<i> may be used in the generation of a baseband envelope (or pulse shaping signal) for a higher frequency oscillator signal as will be described in the following.

The transistors 509 at which the baseband component signals bb<i> are received serve to amplify the baseband component signals bb<i>, and allow the application of a weighting value w<i> to each of the baseband component signals bb<i>. The weighting applied to each signal may be identical (e.g. by using identical transistors 509 for each of the baseband component signals bb<i>) or may be selected such that each baseband component signal bb<i> is weighted differently. The weighted signals are collectively output to a mixer 513 in the form of a current sum 511, that takes all of the weighted outputs of the transistors 509 as an input. The current sum may be calculated as:

$$I = {\sum }_{i} b b < i > * w < i >$$

By selection of appropriate baseband component signals bb<i> and/or weighting transistors 509, the current sum 511 can be controlled to provide the form of an appropriate baseband envelope signal for a mixer 513, such as a Gaussian envelope signal. This baseband envelope signal may then be mixed with a local oscillator signal to provide an output signal 515 that may be used, e.g. in RF transmission. In some particularly convenient arrangements such as that shown in FIG. 5, the local oscillator signal may be provided by the clock source 501, i.e. the same source that is used to generate the baseband envelope signal. Using the signal generated by the clock source 501 in the generation of the baseband envelope signal as well as the local oscillator signal advantageously ensures that the baseband envelope signal and the local oscillator signal always remain in phase. This approach also has the benefit of being more power efficient than running a separate local oscillator to combine with the baseband envelope signal.

An example of the generation of a baseband envelope signal in the form of an approximate Gaussian envelope is illustrated in FIG. 6. FIG. 6 shows six weighted baseband component signals bb<0> to bb<5> generated by the signal generator circuit 504, and the timing of the baseband component signals with respect to a gated clock signal 502b generated from a clock signal 502a. The weighted baseband component signals can be seen to transition from a logic low state to a logic high state in a staggered fashion, such that a first weighted baseband component signal bb<0> switches from low to high at a time t₀, a second weighted baseband component signal bb<1> switches from low to high at a time t₁, a third weighted baseband component signal bb<2> switches from low to high at a time t₂, etc. The weighted baseband component signals then each remain high for a predetermined duration, before transitioning back to logic low where they remain thereafter. For example, the first weighted baseband component signal bb<0> switches from low to high at a time t₀, remains high for a duration Δt, then returns to low at a time t₆.

The current sum of all of the weighted baseband component signals is shown in FIG. 6 by the solid line 603. It can be seen that the current sum of the weighted baseband component signals bb<0> to bb<5> takes the form of a staircase signal that ramps up in steps between t₀ and t₅, remains constant between t₅ and t₆, and then ramps down between t₆ and t₁₁. Each increase in amplitude of the current sum can be seen to coincide with one of the weighted baseband component signals transitioning from logic low to logic high. Similarly, every decrease in amplitude of the current sum can be seen to coincide with one of the weighted baseband component signals transitioning back from logic high to logic low.

By appropriately selecting the timing, duration and amplitude of the weighted baseband component signals, the current sum can be controlled to approximate the form of a signal having a desired shape. For example, as shown in FIG. 6, the current sum of the weighted baseband component signals shown by the solid line 603 can be made to approximate the form of a Gaussian pulse, which may be used as a wave envelope (shown by the dashed line 605). By mixing this signal with the clock signal 502a using a mixer 513, an amplitude modulated mixed signal 602 may be generated from the clock signal and the Gaussian envelope that can be provided at an output, e.g. to be transmitted as an RF pulse.

Although the example of a Gaussian envelope is shown in FIG. 6, it will be appreciated that the baseband component signals bb<i> may be combined to form pulses of arbitrary shape, by generating and weighting pulses of appropriate lengths and start times. The Gaussian envelope is particularly useful for transmissions in the unlicensed ultrawideband spectrum as it makes efficient use of the spectrum mask and is therefore power efficient.

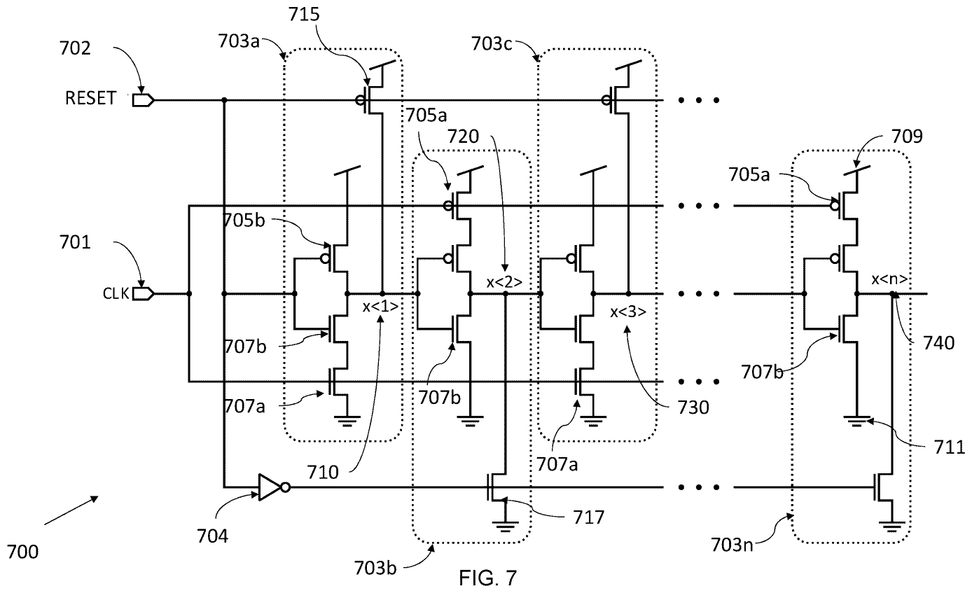

In some embodiments, a signal generator circuit 700 including a reduced number of components may be used in place of the signal generator circuit 100 shown in FIGS. 1 to 3. An example of such a signal generator circuit 700 is shown in FIG. 7. The alternative signal generator circuit 700 comprises two inputs 701, 702 arranged to receive a clock signal and a reset signal respectively, in a manner equivalent to the clock input 101 and reset input 102 described in relation to FIG. 2. The clock signal 701 and the reset signal 702 are used to control the generation of multiple rising and/or falling edge signals x<1:n> as will be explained in the following.

As in the signal generator circuit 100, the signals received at the clock input 701 and the reset input 702 are provided to a cascade of core elements 703 (which may also be referred to as cascade elements), which are connected in sequence. Although four core elements 703a, 703b, 703c and 703n are shown in FIG. 7, it will be appreciated that the signal generator circuit 100 may include fewer, e.g., two or three, core elements, or could include a greater number of core elements, e.g. five, ten, one hundred core elements etc., as represented by the dotted line between the third core element 703c and the nth core element 703n in FIG. 7.

As in the signal generator circuit 100, each of the core elements 703 is arranged to generate a respective rising/falling edge signal x<i> based on the clock signal 701 and the reset signal 702. As with FIG. 2, it will be appreciated that the first core element 703a may receive its input from a separate initial cascade input rather than from the reset input 702. The reset input 702 is used in FIG. 7 to provide the initial cascade input for convenience. The initial cascade input signal propagates through a cascade of core elements 703. The core elements 703 each comprise a ‘core’ PMOS transistor 705b and a core NMOS transistor 707b and a further reset transistor, which may be either a PMOS reset transistor 715 or an NMOS reset transistor 717, depending on the reset state of the core element 103 with which it is associated in the sequence of core elements 703. The signal generator circuit 700 includes two types of core element 703, having either a PMOS reset transistor 715 (e.g. 703a, 703c in FIG. 7) or an NMOS reset transistor 717 (e.g. 703b, 703n in FIG. 7). The two types of core element 703 are cascaded alternately, such that a core element 703 having a PMOS reset transistor 715 is followed in the sequence of core elements 703 by a core element having an NMOS reset transistor 117, which is followed in the sequence of core elements 703 by a core element having an PMOS reset transistor 715, and so on.

Each core element 703 includes a core PMOS transistor 705b and a core NMOS transistor 707b that are connected to form an inverter. However, unlike the embodiment shown in FIG. 2, the layout of the core transistors of each of the core elements 703 alternates in a manner comparable to that of the reset transistors 715 and 717.

Specifically, as well as the core PMOS transistor 705b and the core NMOS transistor 707b that form an inverter, ‘odd numbered’ core elements, e.g. core element 703a, 703c, include a single additional NMOS transistor 707a connected with the inverter in series between a voltage supply rail 709 and ground 711, as well as a PMOS reset transistor 115 arranged to receive the reset signal from the reset input 702. Even numbered core elements, e.g. core element 703b, 703n, include a single additional PMOS transistor 705a connected with the inverter in series between a voltage supply rail 709 and ground 711, as well as an NMOS reset transistor 717 arranged to receive the reset signal from the reset input 702. As in the signal generator circuit shown in FIG. 2, the NMOS reset transistor 717 is connected to the reset input 702 via an inverter 104, such that the reset signal has the same effect on both the PMOS reset transistors 115 and the NMOS reset transistors 117.

The single additional core transistor 705a or 707a in each core element 703 is arranged to receive the clock signal from the clock input 101, such that the core elements 703 each form a clocked inverter using only a single additional core transistor. This allows clocking of the inverter of each core element 703 to take place with a reduced number of transistors in the signal generator circuit 700.

Each core element 703 is arranged to receive a cascade signal output by the preceding core element (and in the case of the first core element 703a, to receive the reset signal from the reset input 702 or separate initial cascade input source), and to generate a rising/falling edge signal x<i> at an output node in response, in a manner equivalent to that described in relation to the signal generator circuit shown in FIG. 2. The rising/falling edge signal x<i> output of each of the core elements 703a-703n is shown in FIG. 7 as x<1>, x<2>, x<3> and x<n> at the output nodes 710, 720, 730 and 740 respectively. The generation of rising/falling edge signals using the cascade of core elements 703 takes place in the same way as for the core elements 103 described in relation to FIG. 2, and hence a full description of the propagation of signals through the cascade of core elements 703 is not repeated here.

The reset transistors 715, 717 serve the same function as the reset transistors 115, 117 shown in FIG. 2, i.e. they are used to return the output nodes 710, 720, 730, 740 to their reset states and to prevent drift at the nodes 710, 720, 730, 740 of the signal generator circuit 700 when it is not in use, by placing and holding the core elements 703 in a reset state.

However, in the signal generator circuit 700, the reset transistors 715, 717 are not strictly required and may not be included in some embodiments. This is a result of a single core transistor 705a or 707a being used to clock the inverter of each core element 703. Such an arrangement means that even in the case that the circuit is not in use, and the reset signal is low, the nodes of each core element do not drift, but are instead pulled up or down by the core transistor that is connected directly to a supply rail 709 or ground 711 (i.e. not connected via the additional clocking transistor). For example, even when the reset signal is low, the first node 710 will be pulled up by the PMOS transistor 705b of the inverter of the first core element 703a. Similarly, the second node 720 will be pulled down by the NMOS transistor 707b of the inverter of the second core element 703b. This means that there is no opportunity for the output x<i> at each of the nodes to drift, even when the signal generator circuit 700 is in the reset state. Moreover, the reset transistors 715, 717 are also not strictly required to return the core elements 703 to their respective reset states after a cascade signal has propagated through the cascade chain. Changing the initial cascade input to a low state will cause the core PMOS transistor 705b of the first core element 703a to pull the output node 710 high (to a reset state) which in turn immediately (without having to wait for a clock transition) causes the NMOS core transistor 707b of the second core element 703b to pull the output node 720 low (to a reset state) and so on. Thus, a reset signal can be propagated through the cascade chain, resetting the output nodes one by one in turn. Reset signals may therefore be optional in certain embodiments. It may nonetheless be preferable to include reset transistors 715 and 717 as shown in FIG. 7 as it will still take some time for the output x<i> at each of the nodes to be pulled low/high, as this relies on the cascade signal propagating through each of the core elements 703. Even though this reset propagation does not require waiting for clock transitions, it still takes finite time and thus it is still faster to reset the whole circuit using the reset transistors 715, 717 as these can pull all output nodes 710, 720, 730, 740 to their reset states simultaneously.

The signal generator circuits 100, 700 described above advance one core element for each rising edge of a clock signal and for each falling edge of the clock signal.

A higher time precision may be accomplished by providing two instances of the signal generator circuit 100, 700, one signal generator circuit arranged to produce a falling edge in the odd numbered output signals x<i> and a rising edge in the even numbered output signals x<i> (as in FIGS. 2 and 7) and the other parallel signal generator circuit 100, 700 arranged to produce a rising edge in the odd numbered output signals x<i> and a falling edge in the even numbered output signals x<i>. Such a differential structure with both signal generator circuits driven from the same clock will provide a rising edge and a falling edge output signal for each x<i> that are well-aligned in time. This allows the start<i> and stop<i> signals to be generated with fewer inverters and thus reduced delays, resulting in higher time precision in the output sequence, e.g. in the baseband component signals bb<i> of FIGS. 5 and 6.

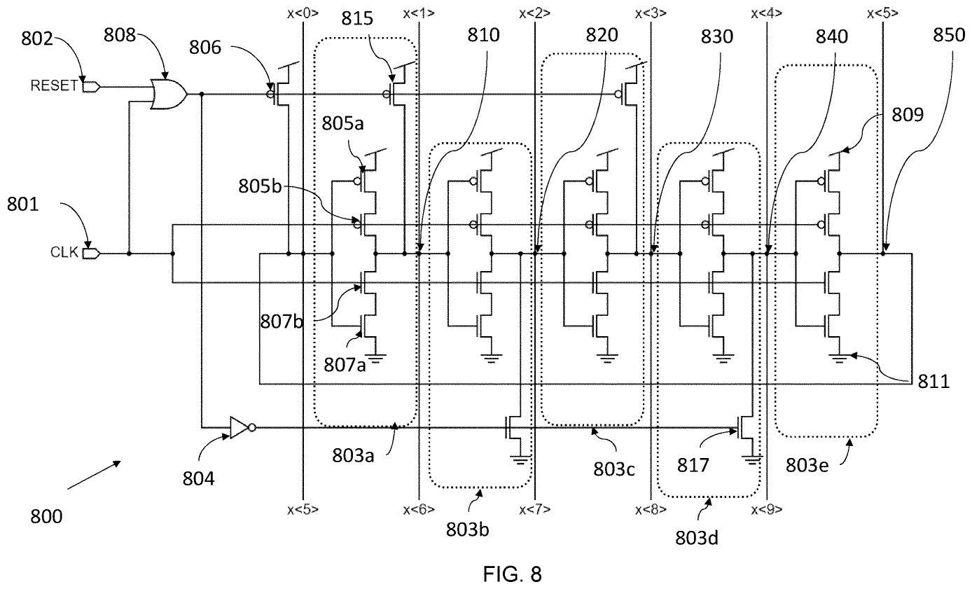

It has also been recognised that the effective length of the cascade of core elements may be doubled by propagating a second and opposite edge through the cascade after the first one has passed through. This may be achieved by providing a second and opposite edge directly to the first element of the cascade, or may be achieved by providing a cascade comprising an odd number of core elements, and providing the output of the last core element in the cascade to the input of the first element of the cascade. An example of a signal generator 800 arranged to operate in this way is shown in FIG. 8.

The signal generator 800 has the same general structure as the signal generator 100 shown in FIG. 2, and comprises two inputs 801, 802 arranged to receive a clock signal and a reset signal respectively, in a manner equivalent to the clock input 101 and reset input 102 described in relation to FIG. 2. The clock signal 801 and the reset signal 802 are used to control the generation of multiple rising and/or falling edge signals x<0:9> as will be explained in the following.

The signals received at the clock input 801 and the reset input 802 are provided to a cascade of cascade elements 803a-803e, which are connected in sequence. Although five cascade elements are shown in FIG. 8, it will be appreciated that the signal generator circuit 800 may include fewer, i.e. two or three, core elements, or could include a greater number of core elements as described above in relation to FIGS. 2 and 7.

Each of the core elements 803 is arranged to generate a first respective rising/falling edge signal (x<0:5>), as well as a second respective rising/falling edge signal (x<6:9>) based on the signal from the clock input 801 and the reset signal 802. The second respective rising/falling edge signals are generated by propagating a second and opposite edge through the cascade after the first one has passed through as will be described in the following.

The reset input 802 is arranged to output a reset signal, via an OR gate 808 to a PMOS transistor 806 (acting as a reset element), arranged to pull the node x<0> high in the reset state. In response to the OR gate outputting high, the PMOS transistor 806 is switched off as reset signal 802 passed through the OR gate 808 and provided at the gate of the PMOS transistor 806 goes high. After the PMOS transistor 806 is switched off, the x<0> node remains high (but floating). The OR gate 808 is also arranged to receive an input from the clock input 801 to prevent short circuits at the x<0> node if the clock signal goes high while the reset signal is low.

To start the signal generator circuit 800, the signal received by the signal generator at the reset input 802 is switched from low to high, and the clock received by the signal generator circuit 800 at the clock input 801 is then started.

When the reset signal goes high, the output node 810 is disconnected from the voltage supply rail at the source of the PMOS reset transistor 815 as the PMOS reset transistor 815 is switched off. As the clock signal first goes high after the reset signal goes high, the output node 810 is connected to ground 811, as the NMOS transistor 807b is switched on by the clock signal, and the NMOS transistor 807a is already on by virtue of the floating high input to the core element 803a.

This causes the output x<1> of the first core element 803a to be pulled low shortly after the signal received at the clock input 801 becomes high, e.g. after several picoseconds.

The high clock signal causes the core PMOS transistor 805b to disconnect the output node 810 from the voltage supply rail 809, and causes the NMOS transistor 807b to connect the output node 810 to ground 811, such that the output node 810 is pulled low (corresponding to the set state of the first core element 803a). The output node 810 therefore switches from high to low when the clock signal is received by the first core element 803a, causing a falling edge in the output signal x<1>. This acts as the first step in the clocked propagation of the first set of cascade signals through the cascade of core elements 803.

In response to the falling edge in the output signal x<1>, the core PMOS transistor 805a of the second core element 803b becomes conducting, but the PMOS clock transistor 805b of the core element 803b remains non-conducting until the clock signal 801 transitions to low, such that the output node 820 remains disconnected from its set state (high) until the clock signal transitions low. In a manner equivalent to that described in relation to FIG. 2, when the clock input 801 goes low, both of the two core PMOS transistors 805a, 805b will be conducting and will pull the output x<2> of the second core element 803b high (i.e. to its set state). The second output node 820 therefore switches from low to high when the clock signal switches from high to low, causing a rising edge in the output signal x<2>. This acts as the second step in the clocked propagation of the first set of cascade signals through the cascade of core elements 803.

This process continues as described earlier in this disclosure, with the state of each core element 803 dependant on the state of the previous core element 803 in the sequence. The state of each core element 803 only changes after the previous core element 803 has flipped and the next rising/falling edge of the clock signal is received. Each core element 803 provides an edge on its output signal x<1:5> at the time the respective core element 803 changes state. As described above, the time at which the state of each core element 803 changes relies on the frequency of the clock signal received at the clock input 801, as well as the position of each core element in sequence.

In contrast to the signal generator circuits 200 and 700 shown in FIGS. 2 and 7, the output of the final core element 803e of the signal generator circuit 800 is provided back to the input of the first core element 803a, where it initiates propagation of a second cascade signal through the signal generator circuit. As there are an odd number of core elements 803, the output of the final core element 803e is a falling edge. The falling edge causes a low signal to be received at the input of the first core element 803a, causing the uppermost core PMOS transistor 805a to become conducting and capable of connecting to the voltage supply rail at its source, and causing the lowermost NMOS transistor 807a to become nonconducting and thus disconnecting the output node 810 from ground 811. The output node 810, which was pulled low during the first propagation, remains low until the clock signal is driven low. At this point, the lower core PMOS transistor 805b is switched on by the low clock signal, and the output node 810 is connected to the voltage supply rail at the source of the uppermost core PMOS transistor. This causes the output node 810 to be pulled high, i.e. to generate a rising edge as an output signal x<6>.

In response to the rising edge in the output signal x<6>, the core PMOS transistor 805a of the second core element 803b becomes nonconducting, and the core NMOS transistor 807a becomes conducting. The core NMOS transistor 805b of the core element 803b remains non-conducting until the clock signal 801 transitions to high, such that the output node 820 only transitions low once the clock signal 801 is driven high. At this time, both of the two core NMOS transistors 807a, 807b will be conducting and will pull the output x<7> of the second core element 803b low. The second output node 820 therefore switches from high to low when the clock signal switches from low to high during the second propagation, causing a falling edge in the output signal x<7>. This acts as the second step in the clocked propagation of the second set of cascade signals through the cascade of core elements 803.

This process continues as described above, with the state of each core element 803 being dependant on the state of the previous core element 803 in the sequence, and switching to the opposite state to that entered when the first set of cascade signals was propagated through the series of core elements 803. The state of each core element 803 only changes state after the previous core element 803 has flipped and the next rising/falling edge of the clock signal is received. Each core element 803 provides a second output signal x<6:9> at the time the respective core element 803 changes state. As described above, the time at which the state of each core element 803 changes relies on the frequency of the clock signal received at the clock input 801, as well as the position of each core element in sequence.

Thus, by providing a cascade comprising an odd number of core elements 803a, and providing the output of the last core element in the cascade to the input of the first core element 803a of the cascade to begin a second propagation of signals through each of the core elements 803, effectively doubling the length of the cascade of core elements 803.

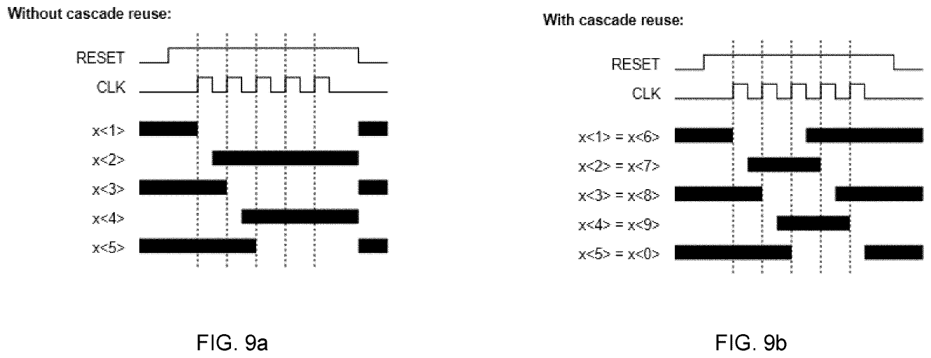

A comparison of the output signals generated in a signal generator circuit employing the re-use of cascade signals as described in relation to FIG. 8 (e.g. signal generator 800), and output signals generated in a signal generator circuit not employing this method is illustrated in FIGS. 9a and 9b. FIG. 9a shows a first timing diagram illustrating the timing of the output signals x<1:5> of five respective core elements of a signal generator circuit as shown in FIG. 2 (i.e. without re-use of cascade signals). FIG. 9b shows a second timing diagram illustrating the timing of the output signals x<0:10> of five respective core elements of a signal generator circuit as shown in FIG. 8 (i.e. with re-use of cascade signals). In the timing diagrams of FIGS. 9a and 9b, a high output signal is shown in black, while a low output signal is illustrated by the absence of a high signal.

In the timing diagram shown in FIG. 9a, it can be seen that odd-numbered output signals are high in the reset state and transition low in the set state with sequential rising edges of the clock signal. Even-numbered output signals can be seen to be low in the reset state and transition high in the set state with sequential falling edges of the clock signal. The timing diagram in FIG. 9a shows that that for a signal generator circuit without re-use of cascade signals, a single reset pulse causes each core element to transition state only once between the reset signal being set to high and the reset signal returning to its initial low state.

In contrast, the timing diagram illustrated in FIG. 9b shows that for a signal generator circuit with re-use of cascade signals, a single reset pulse causes each core element to transition state twice between the reset signal being set to high and the reset signal returning to its initial low state. Each transition is provided at a respective output x<0:9>. For example, the first core element is used to provide the output signals x<0> and x<6>. Initially, the output of the first core element is high, and a falling edge can be seen in an output signal x<1> triggered by the first rising edge of the clock. This output corresponds to the first propagation of signals through the cascade. At a later time during the same reset pulse, the output x<6> of the first core element becomes high, triggered by a falling edge of the clock. This output corresponds to the second propagation of signals through the cascade. Each core element produces one rising edge on its output and one falling edge on its output.

FIGS. 9a and 9b therefore show that the re-use of core elements effectively doubles the length of the cascade of core elements by providing twice as many output signals (i.e. rising and falling edges) for each reset signal.

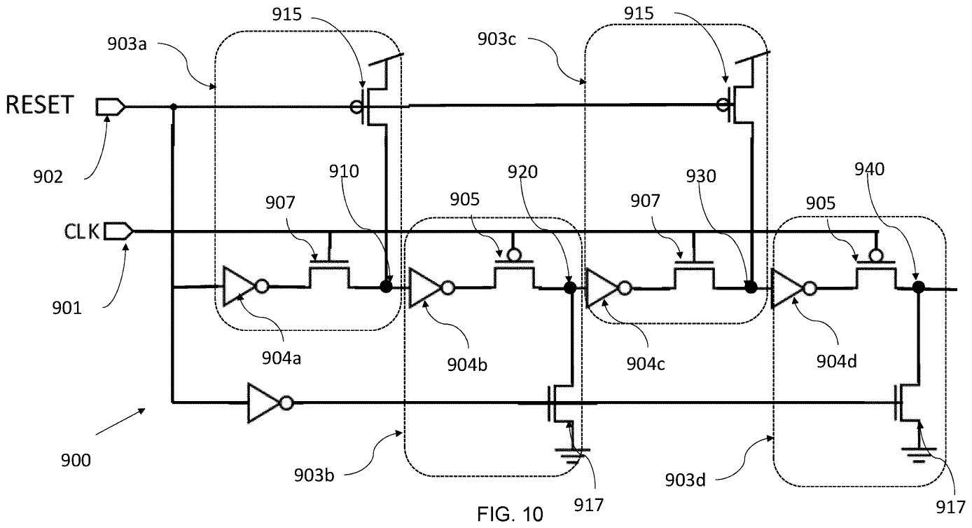

It has been further recognised that a signal generator comprising an alternative core element design may be used in a pulse generator as described herein, in order to generate a plurality of output signals, each having a predetermined duration and start time defined by a particular rising or falling clock edge. A signal generator 900 employing such an alternative signal generator circuit is shown in FIG. 10.

The signal generator circuit 900 can be seen to comprise a series of core elements 903a-903d, each comprising an inverter 904a-904d, either a PMOS transistor 905 or an NMOS transistor 907 arranged to receive a clock signal from a clock source 901, and either a PMOS reset transistor 915 or an NMOS reset transistor 917, connected at an output node 910-940 of a respective core element 903a-903d and arranged to receive a reset signal from a reset input 902.

The timing of the clock signal received at the clock input 901 of the signal generator circuit 900 from a clock source, as well as the timing of the reset signal received at the reset input 902 of the signal generator circuit 900, may be used to control the generation of multiple rising and/or falling edge signals x<1:n> as will be explained in the following.

Initially, the reset input 902 is low, such that the output nodes 910, 920, 930 and 940 are held in a reset state defined by the reset elements 915, 917, all of which are conducting. When the reset input 902 goes high, the output nodes 910, 920, 930 and 940 are effectively disconnected from the rails by the reset elements 915, 917, which no longer receive the required input at their gates to conduct.

The reset signal input at the inverter 904a of the first core element 903a is thus able to propagate through the signal generator 900 based on the state of the clock signal received at the PMOS transistors 905 and NMOS transistors 907 from the clock input 901. When the reset signal initially becomes high, the output of the inverter 904a of the first core element 903a is low. When the clock signal is initially low, the output of the inverter 904a of the first cannot propagate as the NMOS transistor 907 of the first core element 903a is switched off.

When the clock goes high however, the low output of the first inverter 904a is provided to the first output node 910, as well as to the inverter 904b of the second core element 903b. The inverter 904b of the second core element 903b outputs high in response, but this high output cannot propagate as the PMOS transistor 905 of the second core element 903a is switched off as it receives a high input at its gate. However, when the clock signal again goes low, the output of the inverter 904b of the second core element 903b is provided at the second output 920.

This process continues, with the output of each core element being provided to the next core element in sequence with each rising and falling edge of the clock signal. When an output signal has been received at each of the output nodes, the signal generator circuit 900 may be reset by switching the reset input 902 to low, causing the reset elements 915, 917 to conduct and pull and hold their respective output nodes to the reset states.

Although each core element 903 of the signal generator circuit 900 is shown with a reset transistor 915, 917, it will be appreciated that in some embodiments, the reset transistor may not be required. Instead, the reset state of each core element 903 may simply be defined before the clock signal is started. The change of state of each core output 910-940 from the initial state may then be taken as the core element 903a-903d entering the set state. Reset may be achieved by propagating the opposite state through the whole chain in a second pass.

Although four core elements 903a, 903b, 903c and 903d are shown in FIG. 10, it will be appreciated that the signal generator circuit 900 may include fewer, e.g., two or three, core elements, or could include a greater number of core elements, e.g. five, ten, one hundred core elements etc. The number of core elements present in the signal generator circuit 900 may be selected based on the required properties of a pulse generator circuit in which the signal generator circuit 900 is situated. If a greater variety of output pulses (e.g. many pulses of different durations or of longer durations) are required, more core elements 903 may be included in the signal generator circuit 900.

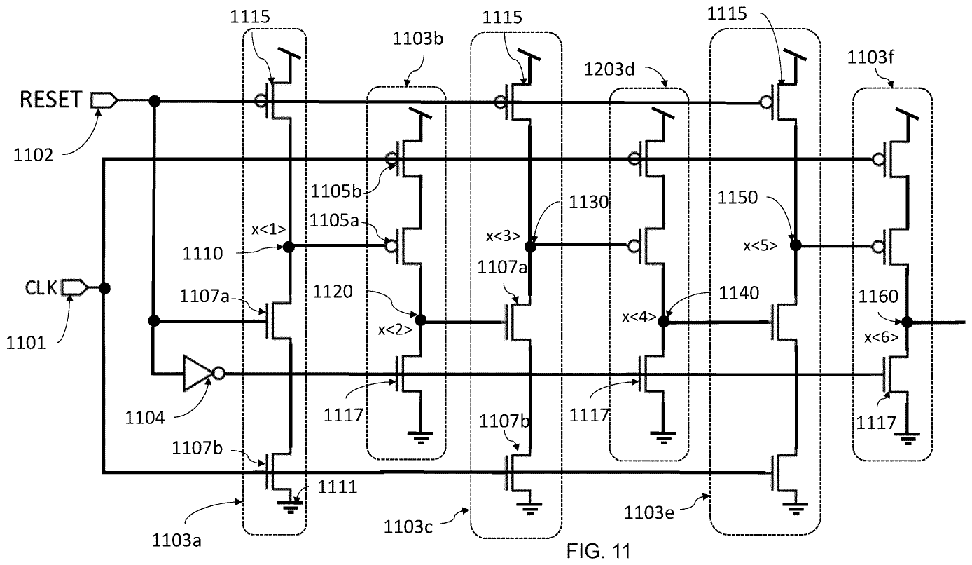

In some embodiments, a signal generator circuit 1100 including a further reduced number of components to that shown in FIG. 7 may be used in place of the signal generator circuits 100, 700, 800 shown in FIGS. 1 to 10. An example of such a signal generator circuit 1100 is shown in FIG. 11.

The signal generator circuit 1100 comprises two inputs 1101, 1102 arranged to receive a clock signal and a reset signal respectively, in a manner equivalent to the clock input 101 and reset input 102 described in relation to FIGS. 2 and 7. The clock signal 1101 and the reset signal 1102 are used to control the generation of multiple rising and/or falling edge signals x<1:6> as will be explained in the following.

As in the signal generator circuits 100 and 700, the signals received at the clock input 1101 and the reset input 1102 are provided to a cascade of core elements 1103 (which may also be referred to as cascade elements), which are connected in sequence. Although six core elements 1103a-f are shown in FIG. 11, it will be appreciated that the signal generator circuit 1100 may include fewer, e.g., two or three, core elements, or could include a greater number of core elements, e.g. five, ten, one hundred core elements etc.

As in the signal generators 100 and 700 described above, each of the core elements 1103 is arranged to generate a respective rising/falling edge signal x<i> based on the clock signal from the clock input 1101 and the reset signal from the reset input 1102.

The clock signal is provided to all of the core elements 1103 simultaneously. The reset signal is provided to reset elements 1115, 1117 simultaneously. Additionally, the signal from the reset input 1102 is provided at an input of the first core element 1103a, which then generates a cascade signal that propagates through the cascade of core elements 1103. Although FIG. 11 shows the reset signal being provided to the first core element 1103a to generate the cascade signal, the first core element 1103a may instead receive its input from a separate initial cascade input instead of from the reset input 1102.

The signal generator circuit 1100 includes two types of core element 1103 having either a PMOS reset transistor 1115 (e.g. 1103a, 1103c, 1103e in FIG. 11) or an NMOS reset transistor 1117 (e.g. 1103b, 1103d, 1103f in FIG. 11). The reset transistors 1115 and 1117 work in the same way as the reset transistors of the signal generator circuits described in relation to FIGS. 2 and 7. Each of the core elements 1103 comprises two ‘core’ transistors and a ‘reset’ transistor. The two core transistors of each core element are either both PMOS transistors 1105 or are both NMOS transistors 1107. The reset transistor is an NMOS reset transistor 1117 for core elements having PMOS core transistors 1105, and is a PMOS reset transistor 1115 for core elements 1103 having NMOS core transistors 1107.

The two types of core element 1103 are arranged alternately, such that a core element 1103 having a PMOS reset transistor 1115 is followed in the sequence of core elements 1103 by a core element having an NMOS reset transistor 1117, which is followed in the sequence of core elements 1103 by a core element having an PMOS reset transistor 1115, and so on.

The propagation of cascade signals through the series of core elements of the signal generator circuit 1100 operates in a manner equivalent to that described in relation to FIGS. 2 and 7.

To start the signal generator circuit 1100, the signal received by the signal generator at the reset input 1102 is switched from low to high (which switches off all the reset transistors 1115, 1117), and the clock received by the signal generator circuit 1100 at the clock input 1101 is then started after a short delay.

When the reset signal initially goes high, the output node 1110 is disconnected from the voltage supply rail at the source of the PMOS reset transistor 1115 as the PMOS reset transistor 1115 is switched off. The NMOS transistor 1107a is also switched on as it receives a high signal at its input, however the output node 1110 remains high as the NMOS transistor 1107b remains switched off while the clock signal is low.

When the first rising edge of the clock signal occurs, the NMOS transistor 1107b is switched on, and the output node 1110 is pulled low. This causes the PMOS transistor 1105a of the second core element 1103b to be switched on, however the state of the second output node 1120 does not change, as the PMOS transistor 1105b is off while the clock signal is high. When the clock signal next goes low, the PMOS transistor 1105b is switched on, and the second output node 1120 is pulled high.

This causes the NMOS transistor 1107a of the third core element to be switched on, and the cascade signal continues to propagate between adjacent core elements of the signal generator circuit 1100 with each rising and falling edge of the clock signal as described above in relation to the signal generator circuits 100, 700.

The signal generator circuit 1100 can therefore be used to control the generation of multiple rising and/or falling edge signals x<i> at the outputs 1110, 1120, 1130, 1140, 1150 and 1160, that may be used to generate pulses of controllable start time and duration in a manner equivalent to that described above, while advantageously requiring fewer components than the signal generator circuits 100 and 700 shown in FIGS. 1 and 7.

It will be appreciated that while the embodiments described above are all described with the switches being NMOS and PMOS transistors, other switch types may be used so long as the switches respond to the various signals appropriately, i.e. that they open/close or become conducting/nonconducting appropriately in response to a high or low signal. For example the NMOS transistors may more generally be any switch that is nonconducting on a low signal and conducting on a high signal.

Similarly the PMOS transistors may more generally be any switch that is conducting on a low signal and nonconducting on a high signal. It will also be appreciated that with suitable manipulation of the signals (e.g. inclusion of additional inverters), any switch could be used. For example, all switches could be NMOS transistors. In such embodiments, the switches described in the embodiments above as PMOS transistors could be replaced with an NMOS transistor with an inverter at its gate. However, it will also be appreciated that the embodiments described above with NMOS and PMOS transistors are particularly efficient designs requiring only a small number of components to achieve the desired operation.

It will be appreciated by those skilled in the art that the invention has been illustrated by describing one or more specific embodiments thereof, but is not limited to these embodiments; many variations and modifications are possible, within the scope of the accompanying claims.

1. A signal generating circuit comprising a series of cascade elements;
wherein each cascade element comprises:
a cascade input,
a cascade output;
a clock input;
a reset element; and
a first switch and a second switch connected in series between a high rail and a low rail;
wherein the cascade output is taken from an output node, wherein one of the high rail and the low rail is separated from the output node by both the first and second switches;
wherein the first switch is driven by the cascade input;
wherein the second switch is driven by the clock input;
wherein the cascade element has a set state and a reset state, wherein the set state connects the cascade output to said one of the high rail and the low rail and the reset state connects the cascade output to the other of the high rail and the low rail; and
wherein the series of cascade elements comprises a plurality of cascade elements connected together in series such that any two adjacent cascade elements are connected at an intermediate node by connecting a cascade output of one cascade element to the cascade input of the adjacent cascade element,
wherein the second switches of any two adjacent cascade elements in the series are arranged to be driven to opposite states by the clock input; and
wherein at least one output signal of the signal generating circuit is provided by at least one intermediate node.

2. A signal generating circuit as claimed in claim 1, wherein the reset element is connected between the output node and the other of the high rail and the low rail.

3. A signal generating circuit as claimed in claim 1, wherein the reset element comprises a third switch.

4. A signal generating circuit as claimed in claim 3, wherein the first switch and the third switch are driven to opposite states by the cascade input such that the cascade output is disconnected from either the high rail or the low rail depending on the cascade input.

5. A signal generating circuit as claimed in claim 3, wherein the second switch of each cascade element is located between the first switch and the third switch.

6. A signal generating circuit as claimed in claim 3, wherein both the first switch and the third switch are located between the second switch and either the high rail or the low rail.

7. signal generating circuit as claimed in claim 1, further comprising a fourth switch in series with the first and second switches, the fourth switch arranged to be driven by the clock input and arranged on the opposite side of the cascade output to the second switch.

8. A signal generating circuit as claimed in claim 7, wherein the second switch and the fourth switch are arranged to be driven to opposite states by the clock input.

9. A signal generating circuit as claimed in claim 1, wherein the first and second switches are transistors.

10. A signal generating circuit as claimed in claim 9, wherein the switches that are arranged between the cascade output and the high rail are PMOS transistors and wherein the switches that are arranged between the cascade output and the low rail are NMOS transistors.

11. A signal generating circuit as claimed in claim 1, wherein the cascade elements of the series alternate between cascade elements that have a set state in which the cascade output is connected to the high rail and cascade elements that have a set state in which the cascade output is connected to the low rail.

12. A signal generating circuit as claimed in claim 1, wherein the at least one output signal comprises a plurality of output signals each from an intermediate node.

13. A signal generating circuit as claimed in claim 12, wherein each of the plurality of output signals is from a different intermediate node.

14. A signal generating circuit as claimed in claim 1, wherein the at least one output signal comprises a plurality of output signals that are each in the form of a rising edge or a falling edge.

15. A signal generating circuit as claimed in claim 14, comprising a pulse generator arranged to receive two of the output signals and combine them into a pulse signal, wherein the rising or falling edge of one output signal defines the start of the pulse signal and the rising or falling edge of the other output signal defines the end of the pulse signal.

16. A signal generating circuit as claimed in claim 15, wherein the pulse generator is arranged to generate a plurality of pulse signals, each pulse signal having a respective start time and duration determined by two output signals that define the start time and end time of the pulse signal respectively.

17. A signal generating circuit as claimed in claim 16, wherein the plurality of pulses are used to generate an envelope signal.

18. A signal generating circuit as claimed in claim 17, further comprising a mixer configured to mix the clock input with the envelope signal to generate a shaped pulse signal.

19. A signal generating circuit as claimed in claim 15, wherein the pulse generator comprises a logical AND gate or a logical NAND gate.

20. A signal generating circuit as claimed in claim 1, wherein each output signal is provided to a buffering circuit.

21. A signal generating circuit as claimed in claim 20, wherein the buffering circuit comprises a first inverter in series with a second inverter and wherein the output of the second inverter provides a buffered version of the output signal and the output of the first inverter provides a buffered inverted version of the output signal.

22. A signal generating circuit comprising a series of cascade elements;
wherein each cascade element comprises:
a cascade input,
a cascade output;
an inverter; and
a clocking switch driven by a clock input;
wherein the inverter and the clocking switch are arranged in series between the cascade input and the cascade output;
wherein the series of cascade elements comprises a plurality of cascade elements connected together in series such that any two adjacent cascade elements are connected at an intermediate node by connecting a cascade output of one cascade element to the cascade input of the adjacent cascade element;
wherein the clocking switches of any two adjacent cascade elements in the series are arranged to be driven to opposite states by the clock input; and
wherein at least one output signal of the signal generating circuit is provided by at least one intermediate node.

23. A signal generating circuit as claimed in claim 20, further comprising a reset element connected to each intermediate node.

24-36. (canceled)
